(19) United States
(12) Patent Application Publication
(10) Pub. No.: US 2013/0178366 A1
(43) Pub. Date: Jul. 11, 2013

(54) NUCLEAR MAGNETIC RESONANCE PROBE COMPRISING INFRARED REFLECTION PATCHES

(71) Applicant: Richard S. WITHERS, Sunnyvale, CA (US)

(72) Inventor: Richard S. WITHERS, Sunnyvale, CA (US)

(73) Assignee: Agilent Technologies, Inc., Loveland, CO (US)

(21) Appl. No.: 13/344,075

(22) Filed: Jan. 5, 2012

(51) Int. Cl. G01R 33/035; H01L 39/24; G01R 33/341

(52) U.S. Cl. 505/162; 505/410; 324/318; 216/13

(57) ABSTRACT

A nuclear magnetic resonance (NMR) probe comprises a substrate, a probe coil formed on the substrate and comprising a superconducting material, and a plurality of infrared (IR) reflection patches formed on the substrate around the probe coil.

### BACKGROUND

Nuclear magnetic resonance (NMR) technologies, such as NMR spectrometers and imaging systems, allow researchers to observe certain magnetic properties of atomic nuclei. These observations can be used to study basic chemical and physical properties of molecules or other small objects. NMR technologies are commonly used, for instance, to perform research on organic and inorganic molecules in the fields of medicine, chemistry, biology, and pharmacology.

NMR measurements are typically performed by an NMR probe that receives a sample to be studied. The sample is placed in a static magnetic field which aligns the magnetic dipoles of its atomic nuclei. Thereafter, the NMR probe applies a time-varying radio-frequency (RF) magnetic field to the sample to perturb the alignment of the magnetic dipoles. Next, the NMR probe detects the magnetic field generated by the perturbed nuclei as they return to their aligned positions. Finally, the detected magnetic field is analyzed to identify various aspects of the sample, such as its composition, the structure of its molecules, and other valuable information.

The NMR probe typically comprises a probe coil that generates the time-varying magnetic field to be applied to the sample and/or detects the magnetic field generated by the perturbed atomic nuclei as they return to their aligned positions. These magnetic fields typically oscillate in the radio-frequency (RF) range. Accordingly, the probe coil may be referred to as an RF transmitter coil, an RF receiver coil, or an RF transmitter/receiver coil. The probe coil is generally tuned to generate the time-varying magnetic field at the resonance frequency of the atomic nuclei, and to detect magnetic oscillations at the resonance frequency of the atomic nuclei.

The performance of the probe coil can be evaluated according to its quality factor (Q-factor), which indicates its bandwidth relative to a resonant frequency of interest. Q is inversely proportional to the resistance of the coil. Thus, a high-Q coil has lower thermal noise and so, if tuned to the frequency of the sample's nuclei, can detect their magnetic oscillations with high sensitivity. Accordingly, other things being equal, a probe coil with a higher Q-factor can produce higher-sensitivity measurements than a probe coil with a lower Q-factor.

One way to improve the Q-factor of an NMR probe coil is by forming it with a superconducting material. The superconducting material can enhance the sensitivity of the coil, allowing it to respond to relatively small magnetic fields of the sample. To achieve superconductivity, however, the superconducting material must be maintained in a cryogenically cooled environment, such as a cryogenically cooled vacuum chamber.

The vacuum chamber prevents the NMR probe coil and other cryogenic structures from absorbing heat through conduction. Nevertheless, it still allows the NMR probe coil and other structures to absorb heat through radiation, such as black-body radiation from the sample being measured. Unfortunately, this absorption of black-body radiation can lead to thermal gradients in the sample, which tends to deteriorate measurements obtained by the NMR probe. In addition, it adds to the heat load that must be removed by the cryogenic cooling system in order to maintain a steady and low temperature.

### SUMMARY

In a representative embodiment, an NMR probe comprises a substrate, a probe coil formed over the substrate and comprising a superconducting material, and a plurality of patches formed over the substrate and around the probe coil, wherein each of the patches is configured to reflect infrared radiation (IR) from a sample tube within the NMR probe.

In another representative embodiment, an NMR device comprises a center tube configured to receive an sample tube within an annular space, a gas source configured to supply a stream of gas to a portion of the annular space between a watt of the center tube and a wall of the sample tube, a cooled vacuum chamber surrounding the center tube, and a probe structure disposed within the vacuum chamber and comprising a substrate, a superconducting NMR probe coil formed over the substrate, and a plurality of patches formed over the substrate around the NMR probe coil, wherein each of the patches is configured to reflect IR radiation transmitted from the center tube to the vacuum chamber.

In still another representative embodiment, a method of forming an NMR probe comprises forming a first layer of superconducting material over a substrate, forming a second layer of normal metal over the layer of superconducting material, etching the first and second layers to form a spiral or interdigital shaped NMR probe coil of the superconducting material and the normal metal, and etching the first and second layers to form a plurality of patches around the NMR probe coil, wherein the patches are configured to reflect IR radiation from a sample tube within the NMR probe.

### BRIEF DESCRIPTION OF THE DRAWINGS

The described embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a diagram of an NMR probe in accordance with a representative embodiment.

FIG. 2 is a schematic diagram illustrating an NMR probe coil structure in accordance with a representative embodiment.

FIG. 3 is a schematic diagram illustrating a portion of an NMR probe coil shown in FIG. 2 in accordance with a representative embodiment.

FIG. 4 is a schematic diagram of an NMR probe coil structure in accordance with a representative embodiment.

FIG. 5 is a schematic diagram illustrating infrared (IR) reflection patches in the NMR probe coil structure of FIG. 4 in accordance with a representative embodiment.

FIG. 6 is a flowchart illustrating a method of forming an NMR probe coil structure in accordance with a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to within acceptable limits or degree.

As used in the specification and the appended claims and in addition to its ordinary meaning, the term ‘approximately’ means to within an acceptable limit or amount to one having ordinary skill in the art, For example, ‘approximately the same’ means that one of ordinary skill in the art would consider the items being compared to be the same.

The representative embodiments relate generally to NMR measurement technologies such as NMR spectrometers and imaging systems. Certain embodiments provide an NMR probe comprising a superconducting NMR probe coil and a plurality of IR reflection patches formed on a substrate. The IR reflection patches reflect infrared radiation such as black-body radiation to prevent it from being absorbed by the substrate. This can reduce or eliminate thermal gradients in a sample being measured by the NMR probe without substantially degrading an RF quality factor of the NMR probe coil or blocking an RF magnetic field generated by the coil.

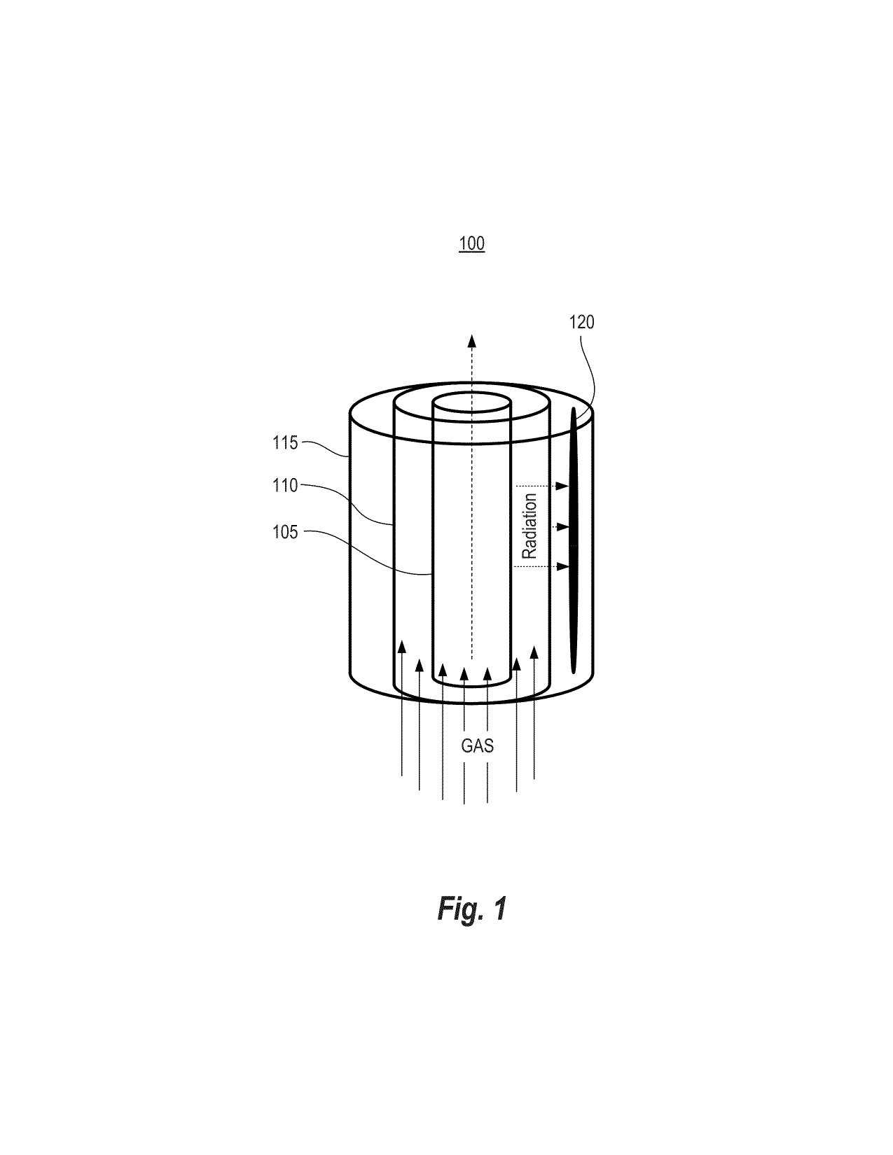

FIG. 1 is a diagram of an NMR probe 100 in accordance with a representative embodiment. This diagram has been greatly simplified to clearly illustrate certain concepts. Moreover, this diagram represents but one example of an NMR probe configuration, and the representative embodiments are not limited to this configuration.

Referring to FIG. 1, NMR probe 100 comprises a sample tube 105, a center tube 110, and a vacuum chamber 115, which are formed as cylinders arranged concentrically about a longitudinal axis indicated by a dotted arrow. NMR probe 100 further comprises at least one superconducting NMR probe coil (hereinafter: “NMR probe coil”) 120 used to generate NMR measurements of a sample placed in sample tube 105. The sample can be contained, for instance, in a small test tube of about 5 mm in outer diameter. NMR probe coil 120 is a tuned circuit and is typically formed of a high temperature superconductor (HTS) material.

Sample tube 105 and center tube 110 are separated by an annular space, and a gas stream (e.g., nitrogen or dry air) is passed through the annular space to control the temperature of sample tube 105. The temperature is typically controlled so that it remains substantially uniform from one end of sample tube 105 to the other. Moreover, the temperature of sample tube 105 and center tube 110 is typically maintained close to room temperature, and it can be controlled to a high level of accuracy, e.g., to within about a tenth of a degree Centigrade.

The temperature of sample tube 105 and center tube 110 is generally controlled through the use of a feedback control system. This system pumps the gas stream from one end of the probe, through the annular space, and out the other end of the probe. Before entering the annular space, the gas stream passes by a heater that heats it to the desired temperature. The gas stream then passes by a sensor that determines the temperature of the gas. The detected temperature is fed back to the control system so that it can adjust the heater to achieve the desired temperature.

Vacuum chamber 115 is hermetically sealed to create a vacuum between NMR probe coil 120 and the outside environment, In an embodiment, the vacuum chamber is cryogenically cooled. The vacuum prevents heat conduction, or convection, from affecting the temperature of NMR probe coil 120 or the outside environment. Within this vacuum, NMR probe coil 120 is cryogenically cooled to a temperature of about 20K or less in order to achieve superconductivity. This cooling can be accomplished, for instance, by connecting a heat exchanger to a substrate of NMR probe coil 120.

Although the vacuum prevents heat conduction between NMR probe coil 120 and the outside environment, thermal energy can nevertheless be transferred in the form of radiation, such as infrared radiation. For example, black-body radiation from sample tube 105 or center tube 110 may emanate toward vacuum chamber 115 and then be absorbed by NMR probe coil 120. In general, black-body radiation from a room temperature object peaks at a wavelength of about 10 μm, which is within a range where a typical sapphire substrate of NMR probe coil 120 is strongly absorbing.

The absorption of black-body radiation by NMR probe coil 120 and other cryogenic structures can cause a gradual decrease in the temperature of the gas stream along its length. In other words, the gas stream may cool down between the time it enters and leaves the annular space between sample tube 105 and center tube 110. This cooling can affect the temperature of the sample located in sample tube 105, potentially producing temperature gradients and/or convection currents in the sample. These temperature gradients and/or convection currents can prevent NMR probe 100 from producing NMR measurements with good lineshape, and they may require more complicated shimming of NMR probe 100. The absorption of black-body radiation by NMR probe coil 120 and other cryogenic structures also adds to the heat load that must be removed from vacuum chamber 115. In a typical implementation, this load can require 5 to 7 kW of alternating current (AC) line power to maintain NMR probe coil 120 at a steady and low temperature.

In view of these and other effects of heat transfer within NMR probe 100, it can be beneficial to prevent NMR probe coil 120 from absorbing black-body radiation, One way of doing this, as will be described below, is to form IR, reflection patches on NMR probe coil 120. These IR reflection patches can reflect black-body radiation to prevent heat transfer without interfering with the transmission of RF fields between NMR probe coil 120 and the sample. This can reduce or eliminate thermal gradients in the sample, and it can potentially reduce the radiated load by a factor of three or more, enabling the use of more economical cooling systems.

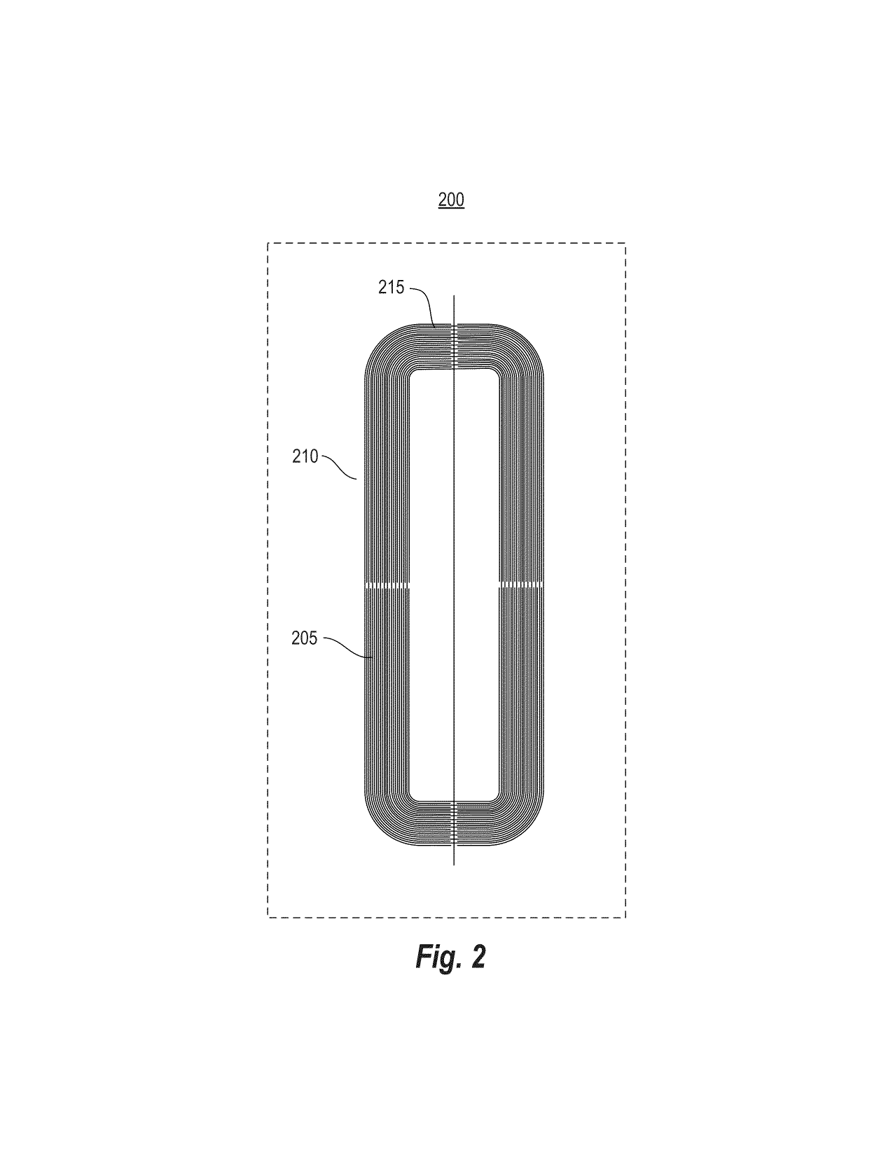

FIG. 2 is a schematic diagram illustrating an NMR probe coil structure 200 in accordance with a representative embodiment. NMR probe coil structure 200 is typically positioned in an NMR probe such as that illustrated in FIG. 1, and it performs transmission and/or reception of electromagnetic signals with respect to a sample in the probe. in other words, it can provide an RF magnetic field to a sample to stimulate its atomic nuclei, and/or receive a corresponding response from the atomic nuclei.

Referring to FIG. 2, NMR probe coil structure 200 comprises a probe coil 205 formed on a substrate 210, Probe coil 205 has a plurality of interdigital capacitors 215 connected in series at opposite ends.

The configuration of probe coil 205 is one of various alternative coil configurations that can be used in an NMR probe. For high frequencies, such as 400 to 900 MHz for measuring 1H and 19F, the configuration with interdigital capacitors (or interwoven combs), as shown in FIG. 2, can be used with 2 to 4 capacitors. The configuration in FIG. 2 happens to be a 4-capacitor interdigital design. For lower frequencies, such as 40 to 200 MHz for measuring ¹³C, ²H, and ¹⁵N, a spiral coil configuration can be used. Moreover, NMR probe coils are not limited to these configurations and can be formed in various alternative ways.

Probe coil 205 is formed of a thin film of material with a normal-metal overlayer. The HTS material and the normal metal are deposited on substrate 210 and then patterned in the shape of a rectangle with curved corners. In a typical configuration, the elements of probe coil 205 are separated from each other by about 30 to 100 μm. The HTS material forms a tuned circuit used to perform transmission and/or reception of electromagnetic signals with respect to the sample. The normal-metal layer prevents burn-out of the HTS film under high-power circumstances by what is called an “RF quench.” It can also prevent degradation by environmental contaminants.

The HTS material can comprise, for instance, yttrium barium copper oxide (YBCO) or various other rare-earth barium copper oxides (ReBCO). Substrate 210 typically comprises a material such as synthetic sapphire. The HTS material is typically formed through an epitaxial growth process in which it is deposited on the substrate by sputtering, evaporation, or one of various other deposition techniques. In some examples, substrate 210 is about 400 micrometers (μm or microns) thick and the HTS material is about 0.3 micrometers thick. The normal-metal can comprise, for instance, gold, silver, or another relatively non-reactive and electrically conductive layer, or a combination of metals such as a thin layer of titanium with a thicker layer of gold on top of it.

NMR probe coil structure 200 is typically used in a cryogenic probe in conjunction with a heat exchanger or other temperature control mechanism. For example, in some embodiments, two probe coils 205 are placed on opposite sides of a sample tube, and a substrate supporting each coil is attached to a heat exchanger. The heat exchanger provides cooling and temperature control of each probe coil 205. During operation, the probe coils 205 are typically cooled to a temperature of about 20 K or lower, which tends to minimize electrical noise (“Johnson” or “thermal” noise) in the HTS material, and can substantially increase its amplitude and power sensitivity.

The windings of probe coil 205 can be inductively coupled to a coupling loop that is electrically connected to an NMR spectrometer. The coupling loop can provide RF energy to probe coil 205 to excite NMR resonance and it can receive a response induced in probe coil 205 from the sample and transmit the response to the spectrometer for processing, recording, and display.

In some embodiments, probe coil 205 is a spiral arranged in a back-to-back configuration with another probe coil wound in the opposite direction. In other words, probe coil 205 can be one of two counterwound spirals. Various examples of counterwound spirals are described in commonly owned U.S. Pat. No. 7,701,217, by Withers et al., the disclosure of which is hereby incorporated by reference. In one example embodiment, the counterwound spirals are configured to resonate at around 150 MHz to detect ¹³C in a 14.1-T magnet. A probe with these spirals can be designed to accept samples in 1.5-mm outer-diameter tubes, for example.

As indicated by the foregoing, an exposed portion of probe coil 205 is formed by a normal-metal such as gold, which is highly reflective of IR radiation. However, as illustrated in FIG. 2, most of the exposed area of NMR probe coil structure 200 is formed by a dielectric substrate material such as sapphire, which is strongly absorptive of IR radiation. Consequently, NMR probe coil structure 200 may absorb a significant amount of IR radiation during operation.

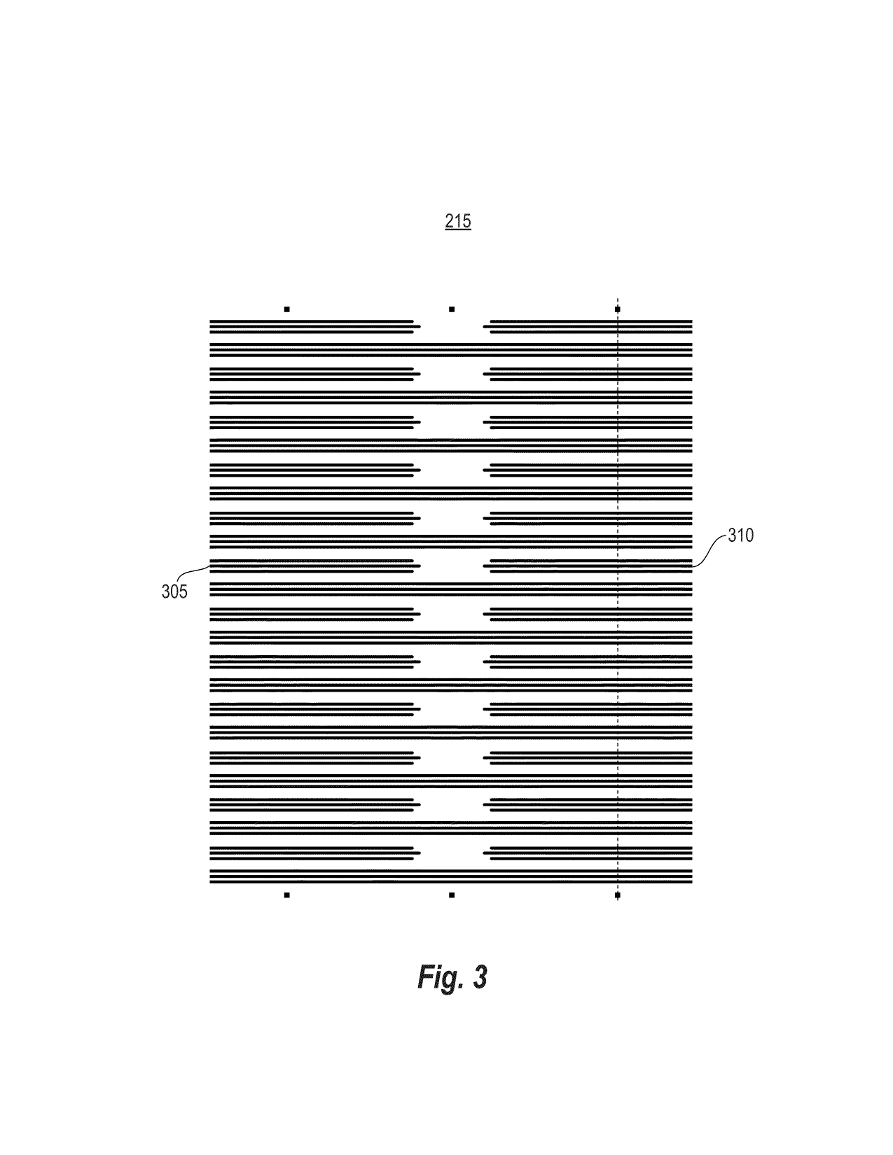

FIG. 3 is a schematic diagram illustrating a portion of probe coil 205 of FIG. 2 in accordance with a representative embodiment. In particular, FIG. 3 shows a close-up of interdigital capacitors 215 at one end of probe coil 205.

Referring to FIG. 3, interdigital capacitors 215 comprise a first interdigital capacitor 305 and a second interdigital capacitor 310 connected in series. These capacitors are located in the windings of probe coil 205, which forms a planar inductor. As illustrated in FIG. 2, there are two additional interdigital capacitors located at another end of probe coil 205, so it includes a total of four interdigital capacitors.

As illustrated by the close-up of FIG. 3, each of first and second interdigital capacitors 305 and 310 and the windings of probe coil 205 include multiple slits that divide them into multiple fingerlets, which are electrically separated from each other along their respective lengths. These slits, although not essential, can potentially improve the performance probe coil 205 by reducing the strength of static magnetic fields generated by persistent current loops in the HTS material. The reduction of these magnetic fields prevents distortion of magnetic field homogeneity in a sample region near NMR probe coil structure 200. In some applications, an adequate reduction can be achieved by limiting the width of each fingerlet to about 10 μm or less. Further examples of such fingerlets and their potential configurations are described in commonly assigned U.S. patent application Ser. No. 13/170,610 filed on Jun. 28, 2011, the disclosure of which is hereby incorporated by reference.

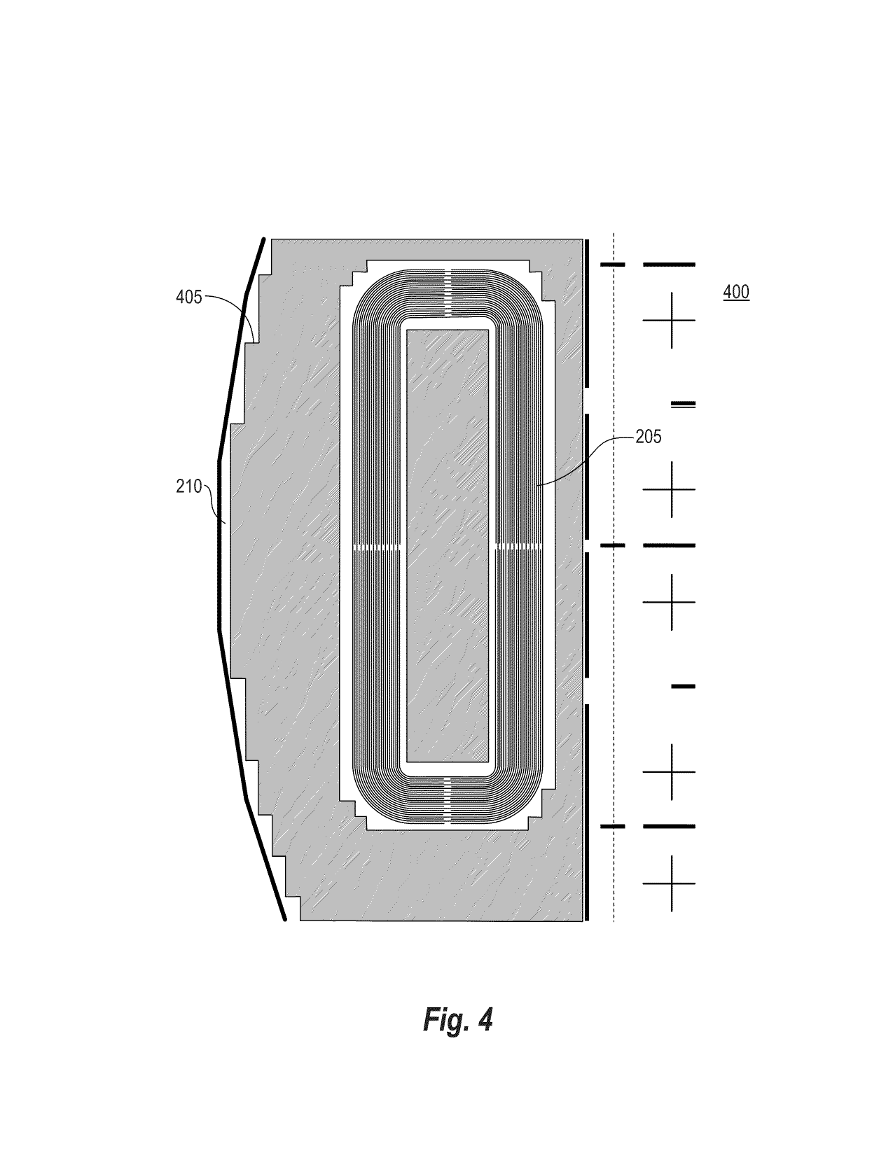

FIG. 4 is a schematic diagram of an NMR probe coil structure 400 in accordance with a representative embodiment. NMR probe coil structure 400 is similar to NMR probe coil structure 200 of FIG. 2, except that it further comprises reflection patches configured to prevent absorption of radiated thermal energy.

Referring to FIG. 4, NMR probe coil structure 400 comprises probe coil 205 and IR reflection patches 405, both formed on substrate 210. IR reflection patches 405 reflect infrared energy to prevent it from being absorbed by substrate 210. This in turn prevents NMR probe coil structure 400 from causing thermal gradients in an NMR sample being measured. The patches can be formed, for example, of an upper layer of gold or another material having high reflectivity of IR energy.

As illustrated in FIG. 4, IR reflection patches 405 are formed in an enclosed center portion of probe coil 205, and they surround an outer perimeter as well. As the total area of exposed substrate decreases, the reflection of IR energy tends to increase accordingly. Consequently, reflection patches 405 may be formed with the greatest coverage that can be attained without substantially interfering with the electromagnetic properties of probe coil 205. To ensure that the RF performance of the probe coil is not impacted negatively by the IR reflection patches, for instance, a probe coil of about 3-5 mm×15-20 mm may be may be separated from the IR reflection patches by a distance of 50 μm,

Probe coil 205 and IR reflection patches 405 are typically formed of the same material and by similar processes, For example, they can both be formed by depositing a layer of YBCO and then a layer of gold on substrate 210, and then etching both of the layers using an etching process such as ion milling, Because the formation of probe coil 205 alone typically requires all of these steps, IR reflection patches 405 can be formed with minimal additional cost compared with the probe coil 205 by itself.

In the example of FIG. 4, substrate 210 comprises a round wafer (e.g., a 3 inch diameter sapphire wafer), and probe coil 205 and IR. reflection patches are formed on an edge portion of the wafer, as indicated by an upper curved line. In a typical implementation, multiple NMR probe coil structures can be formed on different parts of the same wafer. Nevertheless, NMR probe coil structure 400 is not limited to a specific type or configuration of wafer, or to being formed on a particular part of a wafer.

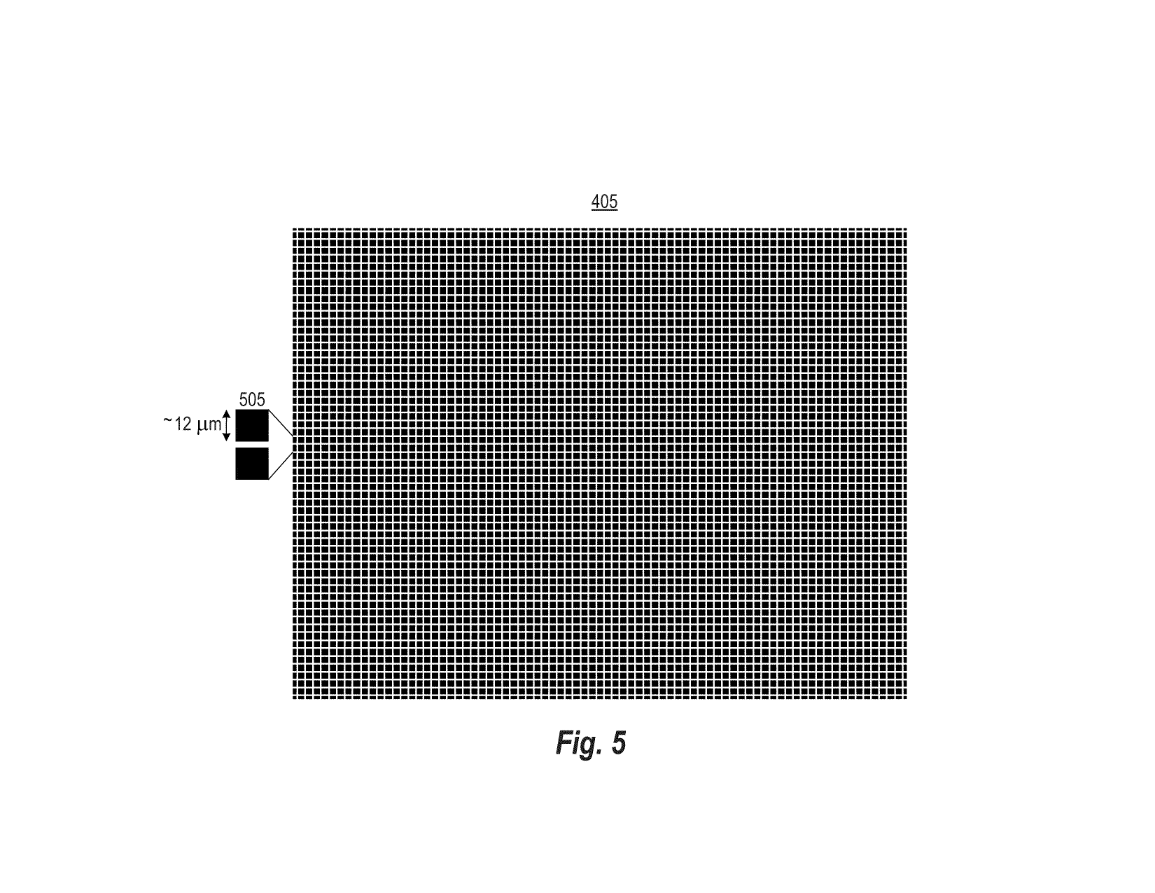

FIG. 5 is a schematic diagram illustrating IR reflection patches 405 in the NMR probe coil structure of FIG. 4 in accordance with a representative embodiment. More specifically, FIG. 5 shows a magnified view of a rectangular region of about 1 mm reflection patches 405 in FIG. 4.

Referring to FIG. 5, IR reflection patches 405 comprise a plurality of separate geometric shapes each formed from a layer of superconducting material such as YBCO covered by a layer of normal-metal such as gold. These squares are separated from each other by etched areas exposing portions of substrate 210. For explanation purposes, it will be assumed that each of the IR reflection patches 405 is a square formed of gold over YBCO.

In general, gold is very reflective in the infrared range, so forming the patches of gold can reduce the thermal absorption of NMR probe coil structure 400 due to IR radiation. However, gold can also block RF energy, so it may interfere with the transmission and reception of signals by probe coil 205. Accordingly, the exposed portions of substrate 210 are formed between IR reflection patches 405 in order to allow RF penetration. As indicated above, these separations can be formed by an etching process such as ion milling, which is used to form probe coil 205.

The dimensions and geometry of IR reflection patches 405 can affect the performance of probe coil 205 in various ways. For example, if the patches are too large, persistent currents may arise in the superconductor material. These persistent currents create their own magnetic field, which can disturb the homogeneity of the static magnetic field and interfere with NMR measurements. On the other hand, if the patches are too small, the proportional area covered by the patches, or filling factor, may decrease. A reduction in filling factor tends to increase the amount of IR energy absorbed by substrate 210, which can contribute to thermal gradients in an NMR sample.

Persistent currents can generally be maintained within an acceptable range by forming IR reflection patches 405 such that their largest dimension, or superconducting structure, has a maximum line width less than or equal to about 12 μm or 10 μm. As an example, FIG. 5 shows a portion 505 of IR reflection patches 405 formed by squares each measuring about 12 μm on a side and separated by a distance of about 3 μm. The dimensions shown in portion 505 can also provide an acceptable filling factor for various applications, particular, these dimensions produce a filling factor of (12/15)², or 64%, which means that the reflection patches 405 fill the majority of the area where they are present and can reduce the amount of heat absorbed by substrate 210 by close to 64%.

Although not shown in the drawings, IR reflection patches 405 can also be combined with other approaches for reducing heat transfer between a sample and NMR probe coil structure 400. For example, one additional approach is to wrap the outside of center tube 110, in the vacuum space, with glass fibers capable of scattering or reflecting infrared radiation. In addition, IR reflection patches 405 can also be modified to have various alternative geometries not shown in the drawings. For example, they can be formed as rectangles, elongated strips, various other polygonal shapes, irregular shapes, and so on.

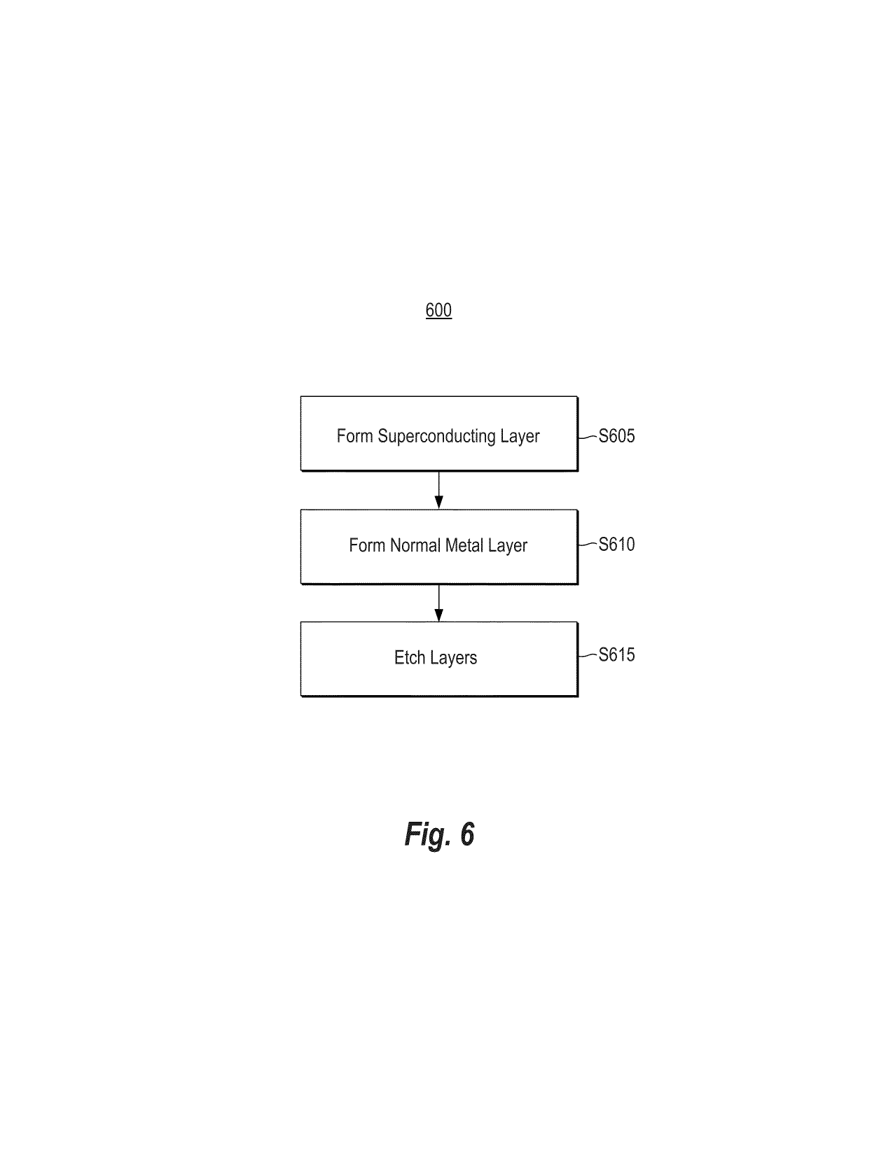

FIG. 6 is a flowchart illustrating a method 600 of forming an NMR probe coil in accordance with a representative embodiment. For explanation purposes, it will be assumed that method 600 is used to form NMR probe coil structure 400 of FIG. 4. However, this method can be used to form other types of NMR probe coil structures,

Referring to FIG. 6, the method begins by forming a film or layer of HTS material on a dielectric substrate (S605). The dielectric substrate typically comprises sapphire, and it can be provided in the form of a wafer suitable for manufacturing multiple probe coils. In one embodiment, the HTS material is formed by inserting the substrate in a co-evaporation chamber and simultaneously evaporating yttrium, barium, and copper to form an initial layer on the substrate. The substrate is then placed in an oxygen atmosphere to oxidize the initial layer. The substrate has a lattice match to YBCO, which allows the deposited elements to grow epitaxially. In certain embodiments, the YBCO is grown to a thickness of about 0.3 μm.

After the HTS material is grown on the substrate, a layer of normal-metal is formed on the substrate over the HTS material (S610). Among other things, this layer can protect he HTS against so-called “RF quench” and environmental contamination or degradation, and it can be used to form IR reflection patches such as those illustrated in FIG. 4.

Next, the layers of normal-metal and HTS material are etched to form a tuned circuit in the form of a spiral such as that illustrated in FIG. 4, and a plurality of IR reflection patches such as those illustrated in FIG. 4 (S615). This etching can be accomplished, for example, by a photolithographic process. In the photolithographic process, a photomask is formed to define the spiral and the reflection patches. The photomask can be formed, for instance, by depositing chromium on glass. Next, photoresist is spun on the HTS material, and the photoresist is exposed using the photomask. Following the exposure, the photoresist is partially removed so that it covers only portions of the normal-metal and HTS material that correspond to the spiral and IR reflection patches. Then, the normal-metal and HTS material are etched to remove portions that are not covered by the photoresist. This etching can be accomplished, for instance, using an ion mill with argon ions. As a consequence of the etching, portions of the substrate are exposed through the layers of normal-metal and HTS material. After the etching, the substrate (e.g., the sapphire wafer) can be diced into individual probe coils, which can be placed within an NMR probe.

In experimental examples of NMR probe coil structure 400, it has been determined that the presence of reflection patches 405 does not significantly reduce the Q-factor or sensitivity of probe coils 205. It has also been determined that the IR reflection patches 405 do not substantially block RF magnetic fields generated by probe coils 205, which also avoids a reduction in the sensitivity of probe coils 205.

For example, in some experiments, it has been determined that the Q-factor of probe coil 205 with IR reflection patches 405 is similar to that of probe coil 205 without IR reflection patches 405. It has also been observed that the resonant frequencies of probe coil 205 appear to be unaffected by reflection patches 405. If the RF magnetic fields of probe coils 205 are blocked by the patches, the coil inductance is reduced and its frequency rises.

Where an RF magnetic field such as that generated by probe coil 205 of FIG. 4, is applied to a conductive square in IR reflection patches 405, a current opposing the magnetic field is induced in the square. This current decays with a time constant given by a ratio of an inductance L of the square to a resistance R of the square. After a time equal to several of these time constants, the current is nearly zero, and the magnetic field penetrates the square, much as if it the square were absent. For a square formed of YBCO covered with gold, this L/R time constant is roughly d/4 seconds, where d is the size of the square in meters. For 12 μm squares, this is 3 μm, and therefore RF magnetic fields at frequencies of interest in NMR will not penetrate the squares. However, experimental measurements have indicated that the RF magnetic fields penetrate the clear spaces between the squares sufficiently unimpeded so that the coil inductance is not substantially reduced. It is reasonable to conclude that the magnetic coupling between coil and sample, and therefore coil sensitivity, is minimally reduced.

While example embodiments are disclosed herein, one of ordinary skill in the art appreciates that many variations that are in accordance with the present teachings are possible and remain within the scope of the appended claims. For example, although various embodiments are described in relation to planar coils, these embodiments could be modified to include cylindrical coils. The invention therefore is not to be restricted except within the scope of the appended claims.

1. A nuclear magnetic resonance (NMR) probe, comprising:
a substrate;
a probe coil formed over the substrate and comprising a superconducting material; and
a plurality of patches formed over the substrate and around the probe coil, wherein each of the patches is configured to reflect infrared (IR) radiation from a sample tube within the NMR probe.

2. The NMR probe of claim 1, wherein each of the patches comprises a layer of normal metal surrounded by an exposed portion of the substrate.

3. The NMR probe of claim 2, wherein the layer of normal metal is formed over a layer of the superconducting material surrounded by the exposed portion of the substrate.

4. The NMR probe of claim 1, wherein the NMR probe coil comprises a layer disposed in a spiral or interdigital configuration over the substrate.

5. The NMR probe of claim 4, wherein the substrate comprises sapphire.

6. The NMR probe coil of claim 4, wherein the layer comprises yttrium barium copper oxide (YBCO).

7. The NMR probe coil of claim 1, wherein each of the plurality of patches comprises a layer of gold surrounded by an etched portion of the substrate.

8. The NMR probe of claim 2, wherein the patches have rectangular shapes.

9. The NMR probe of claim 1, wherein each of the patches has a maximum line width less than or equal to approximately 12 microns.

10. The NMR probe of claim 1, wherein the plurality of patches provides a filling factor of approximately 60% to approximately 70%.

11. The NMR probe of claim 1, wherein the patches surround an outer perimeter of the probe coil and fill a majority of an enclosed center area of the probe coil.

12. The NMR probe of claim 1, further comprising:
a center tube configured to receive the sample tube within an annular space;
a gas source configured to supply a stream of gas to a portion of the annular space between a wall of the center tube and a wall of the sample tube; and
a cooled vacuum chamber surrounding the center tube;
wherein the substrate having the probe coil and the plurality of patches is disposed within the vacuum chamber.

13. The NMR probe of claim 12, wherein the substrate comprises sapphire.

14. The NMR probe of claim 12, wherein the NMR probe coil comprises a layer formed in a spiral or interdigital configuration over the substrate.

15. The NMR probe of claim 14, wherein the layer comprises yttrium barium copper oxide (YBCO).

16. The NMR probe of claim 12, wherein each of the patches comprises a layer of superconducting material, a layer of normal metal formed over the superconducting material, and a region exposing the substrate around the layer of superconducting material and the layer of normal metal.

17. The NMR probe of claim 12, wherein the patches have rectangular shapes each having a maximum width of less than or equal to approximately 12 microns.

18. The NMR probe of claim 13, wherein the patches are separated from each other by a distance of less than about 25% of the maximum width.

19. The NMR probe of claim 12, wherein the patches are configured to reflect more than 50% of IR radiation entering the vacuum chamber from the center tube.

20. A method of forming a nuclear magnetic resonance (NMR) probe, comprising:
forming a first layer of superconducting material over a substrate;
forming a second layer of normal metal over the layer of superconducting material;
etching the first and second layers to form a spiral or interdigital shaped NMR probe coil of the superconducting material and the normal metal; and
etching the first and second layers to form a plurality of patches around the NMR probe coil, wherein the patches are configured to reflect infrared (IR) radiation from a sample tube within the NMR probe.
